(19) United States
(12) Patent Application Publication
(10) Pub. No.: US 2007/0080354 A1
(43) Pub. Date: Apr. 12, 2007

(54) Power package and fabrication method thereof

(75) Inventors: Ming-Yao Lin, Hsinchu Hsien (TW); Ming-Te Lin, Hsinchu Hsien (TW); Sheng-Pan Huang, Hsinchu Hsien (TW); Chia-Chang Kuo, Hsinchu Hsien (TW); Chiu-Ling Chen, Hsinchu Hsien (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/544,046

(22) Filed: Oct. 6, 2006

(30) Foreign Application Priority Data
Oct. 7, 2005 (TW) 094135098

(51) Int. Cl. H01L 33/00

(52) U.S. Cl. 257/79

(57) ABSTRACT

The present invention relates to a combined light emitting diode (LED) package structure and a fabricating method for fabricating the same. The combined LED package structure includes an LED chip, a conductive structure and an encapsulant. The encapsulant encapsulates the LED chip and a portion of the conductive structure. The conductive structure has a thick metal member and a thin metal member. The thick metal member is used for carrying the LED chip, provide heat absorbing and heat dissipating paths to the LED chip, the bottom and a portion of the lateral side thereof are exposed to the outside of the encapsulant to increase heat dissipating area. The thin metal member is electrically connected to the LED chip via at least two conductive leads which are extended to a region outside of the encapsulant to serve as outside electrodes of the LED package structure.

### FIELD OF THE INVENTION

The present invention relates to a power package structure and fabrication method thereof, and more specifically, to a power package having light emitting chips and fabrication method thereof.

### BACKGROUND OF THE INVENTION

LED industry has been developed for over 30 years, the operating power of LED is kept increasing, traditional package types of bulb-shaped LED, SMD LED have no longer met the requirement of heat dissipating. Various kinds of high power LED package structures are introduced, such as the typical Luxeon from Lumileds, Jupiter from Nichia, and Golden Dragon from Osram. Other LED package companies, such as Cree and Toyota, also presented high power LED package structures for encapsulating and fabricating LED related products. A portion of the above high power LED package structures adopted a design of thin metal member encapsulated with plastic plus a heat dissipating base, such as the Luxeon from Lumileds; while another portion adopted a design of thick and thin metal member encapsulated with plastic for achieving high heat dissipating efficiency, such as the Jupiter from Nichia. The fabricating process of the LED package structures adopted the design of thin metal member encapsulated with plastic plus a heat dissipating base, compared with that of the conventional bulb-shaped LED, is more complicated, the fabricating cost thereof is high. Whereas the design of thick and thin metal member encapsulated with plastic has advantage in heat dissipating, however wherein the thick and thin metal member is such a kind of metal material having a portion of its thick area processed into thin area, the design flexibility and size ratio of which will be restricted in subsequent process of patterns and outlines. TW558066 owned by PARA LIGHT ELECTRONICS CO., LTD from Taiwan, and U.S. Pat. No. 6,828,170 B2 owned by Gentex from the United States are examples of patents of LED package adopted thick and thin metal member, the embodiments thereof are as shown in FIG. 1 and FIG. 2. In TW558066, a portion area of a piece of thick metal material 2 is firstly processed into thin metal material to form so-called thick and thin metal member, and the process of cups and external connections 21 is subsequently performed. The design flexibility and size of the above structure are restricted, so that miniaturization cannot be achieved; and also separate surface film plating according to function requirements on a portion area of the metal frame cannot be achieved. In U.S. Pat. No. 6,828,170 B2, the thick and thin metal member is also adopted as the metal frame, the feature of which is still to firstly process the conductive structure into thick and thin metal member, and subsequently to process cups and external connections 31; wherein it is stated that the process method of the thick and thin material thereof is not restricted to the method of firstly process a portion of a piece of thick metal material into thin metal material to form so-called thick and thin metal member, while a method of combining the thick material and the thin material into a thick and thin metal member via soldering or boding, and then cups and external connections 31 are formed on it.

Consequently, how to solve the problem of restriction to the design flexibility and size ratio, and high cost caused by complicated process in the course of processing conventional thick and thin metal member and subsequently outlines, has become a task needs to be faced in related fields.

### SUMMARY OF THE INVENTION

Regarding the drawbacks of the abovementioned conventional technologies, an objective of the present invention is to provide a power package and fabricating method thereof, the conductive structure thereof is a combination of a thick metal member and a thin metal member separately processed, wherein the pattern design, shape design and surface film plating of the thick and thin metal members can be independently performed, therefore benefits on design flexibility and various functions can be achieved, such as increasing heat dissipating protrusions, reducing structure size by stacking the thick and thin metal members, complying to different function requirements by separate film plating and so on.

Another object of the present invention is to provide a power package and fabricating method thereof, whose structure is very simple and easy to be fabricated, which only comprises LED chips, a conductive structure and an encapsulant, whose material combination is similar to conventional bulb-shaped LED without reliability problems caused by multilayer connecting.

Still another object of the present invention is to provide a power package and fabricating method thereof, whose conductive structure retains the heat conducting advantage of thick and thin metal member.

Still another object of the present invention is to provide a power package and fabricating method thereof, whose conductive structure is a combination of the thick metal member and thin metal member separately processed, which is easy to be processed and combined, therefore lowering the fabricating cost.

In accordance with the above and other objectives, the present invention proposes a fabricating method of a power package, comprising following steps: providing a conductive structure as a combination of at least a thick metal member having at least a light reflecting portion formed thereon in advance and at least a thin metal member having a plurality of leads for electrically connecting the power package to external devices; providing at least a light emitting chip arranged in the at least a light reflecting portion on the thick metal member, and electrically connected to the thin metal member; and providing at least an encapsulant for encapsulating the light emitting chip, and covering a portion of the at least a thick metal member and the at lest a thin metal member.

In the step of providing a conductive structure, the thick metal member and the thin metal member are processed separately by punching or etching, which is easy to be processed and easy to be fabricated.

In the step of providing a conductive structure, at least a light reflecting portion and a base are formed on the thick metal member, wherein the light reflecting portion is formed by one of the planar surface, concave surface or convex surface; and at least two conductive leads is formed on the thin metal member, wherein the surface of the thick metal member is performed with bright silver plating for increasing the light reflection for the light emitting chip. The bright silver plating adopts an electrical plating method or a surface coating method. The surface of the thin metal member is performed with foggy silver plating for increasing the yield rate of the wire bonding which is electrically connecting line of the light emitting chip, wherein the foggy silver plating adopts the electrical plating method or the surface coating method.

In the step of providing a conductive structure, the thick metal member and the thin metal member are attached via attaching means; the attaching means can be gluing, punching, mortising or AC/DC soldering. The conductive structure is a combination of components separately processed, wherein the pattern design, shape design and surface film plating of each component can be independently performed, therefore benefits on design flexibility and various functions can be achieved.

In the step of providing at least a light emitting chip, at least a light emitting chip is arranged in at least a light reflecting portion on the thick metal member, and electrically connected to the conductive leads of the thin metal member.

In the step of providing at least an encapsulant, the light emitting chip, and conductive structure are encapsulated employed encapsulating technology, and a portion of the conductive structure is exposed to the outside of the encapsulant, the fabricating process thereof is very simple therefore reducing the fabricating cost.

A power package achieved by the fabricating method mentioned above, comprising: a conductive structure as a combination of at least a thick metal member having at least a light reflecting portion formed thereon in advance and at least a thin metal member having a plurality of leads for electrically connecting the power package to external devices; at least a light emitting chip arranged in the at least a light reflecting portion on the thick metal member, and electrically connected to the thin metal member; and at least an encapsulant for encapsulating the light emitting chip, and covering a portion of the at least a thick metal member and the at lest a thin metal member, wherein the encapsulant can be resin, glass or transparent plastic.

The thick metal member comprises at least a light reflecting portion and a base; the bottom and a portion of the lateral side of the thick metal member are exposed to the outside of the encapsulant for increasing heat dissipating paths. The light reflecting portion is employed to reflect the light generated by the light emitting chip. The base is employed to carry and secure the encapsulant.

The thin metal member comprises at least two conductive leads.

The conductive structure comprises at least a thick metal member and at least a thin metal member. The thick metal member and the at least a thin metal member can be made of identical or different materials, and the surfaces thereof can be plated with identical or different light reflecting materials.

### BRIEF DESCRIPTION OF THE DRAWINGS

FIG. 1 is a three dimensional view showing a conventional LED package with a thick and thin metal member;

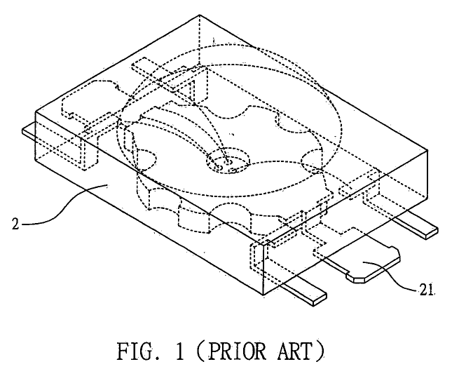

FIG. 2 is a three dimensional view showing the conductive structure of another conventional LED package;

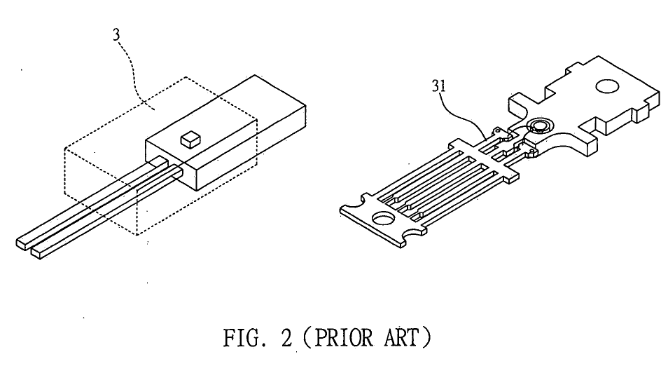

FIG. 3 is a separate view showing the thick metal member and thin metal member of the conductive structure of the present invention;

FIG. 4 is a three dimensional view showing the connecting of the thin metal member and thick metal member of the present invention;

FIG. 5 is a three dimensional view showing the light emitting chips of the present invention connecting to the conductive structure via wire bonding;

FIG. 6 is a schematic view showing a power package of the present invention;

FIG. 7 is two schematic views of the power package of the present invention;

FIG. 8 is a schematic view showing another thin metal member stacked on the original thin metal member in accordance with a second embodiment of the fabricating method of the present invention; and

FIG. 9 is a schematic view showing a light reflecting portion arranged in the package in accordance with a third embodiment of the fabricating method of the present invention.

### DETAILED DESCRIPTION OF THE PREFERRED EMBODIMENTS

The following embodiments are used to describe the present invention; those skilled in the art can easily understand other advantages and functions of the present invention via the contents disclosed in the description. Various embodiments can be employed in the present invention; and the detail of the description can be based on and employed in various points of view, which can be modified within the scope of the present invention.

The following embodiments aims to further detail the feature of the present invention, which shall not be regarded as a limitation to the scope of the present invention.

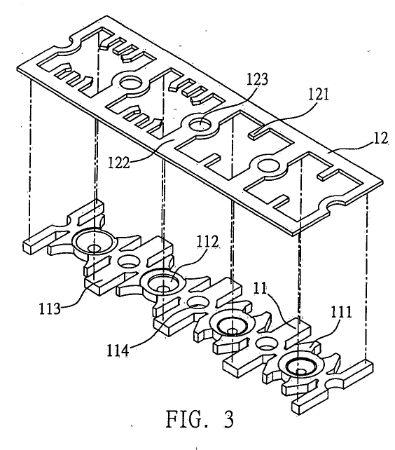

Referring to FIG. 3, a separate view showing the thick metal member 11 and the thin metal member 12 of the power package of the present invention is shown. The thick metal member 11 comprises at least a light reflecting portion 112 and at least a base 111, wherein the light reflecting portion 112 is formed by planar surface, concave surface or convex surface, and the thin metal member 12 comprises at least two conductive leads 121. The thick metal member 11 and the at least a thin metal member 12 can be made of identical or different materials, and the surfaces thereof can be plated with identical or different light reflecting materials. The surface of the thick metal member 11 is performed with bright silver plating for increasing the light reflection from the LED chips. The bright silver plating can adopt an electrical plating method or a surface coating method. Therefore, the thick metal member 11 can keep a heat-conduction advantage of conventional thick and thin metal member. The surface of the thin metal member 12 is performed with foggy silver plating for increasing the yield rate of the wire bonding which is electrically connecting line of the light emitting chip, The foggy silver plating can adopts electrical plating method or surface coating method. The thick metal member 11 and the thin metal member are processed separately by punching or etching.

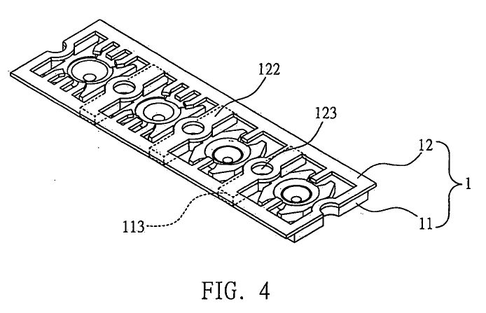

Referring to FIG. 4, a three dimensional view of the thin metal member 12 combined with the thick metal member 11 of the power package of the present invention is shown. At least an attaching portion 122 and an open hole 123 of the thin metal member 12 are aligned to and attached with at least a connecting portion 113 and a fixed hole 114 of the thick metal member 11 via attaching means. The attaching means can be gluing, punching, mortising or AC/DC soldering, so as to form the conductive structure 1. Because the conductive structure 1 is a combination of the thin metal member 12 and the thick metal member 11 separately processed, wherein the pattern design, shape design and surface film plating of each component can be independently performed, therefore benefits on design flexibility and various functions can be achieved.

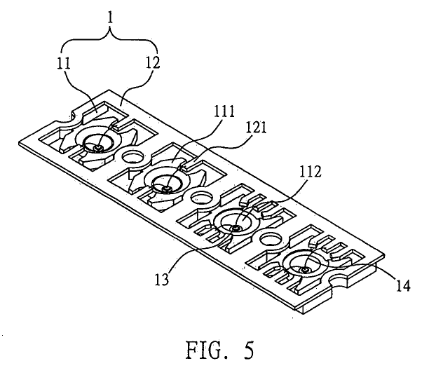

Referring to FIG. 5, a three dimensional view of a light emitting chip electrically connected via bonding wires to a conductive structure of the present invention. A light emitting chip 13 is installed in at least a light reflecting portion 112 of the thick metal member 11 and electrically connected to at least two conductive leads 121 of the thin metal member 12.

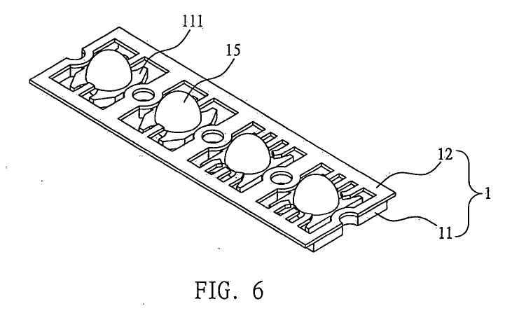

Referring to FIG. 6, a schematic view of a power package of the present invention is shown. The power package comprises at least a conductive structure 1, at least a light emitting chip 13, and an encapsulant 15 for encapsulating the light emitting chip 13 and covering part of the conductive structure 1. The conductive structure 1 has a bottom portion and part of a side portion are exposed to a region outside of the encapsulant 15, so as to increase a number of heat dissipating paths. The encapsulant 15 can be resin, glass or transparent plastic.

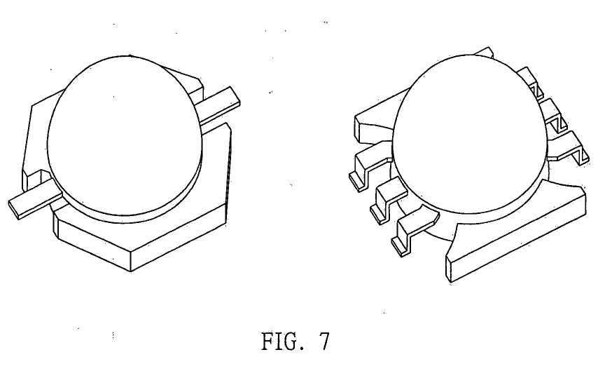

FIG. 7 shows two schematic views of the power package of the present invention.

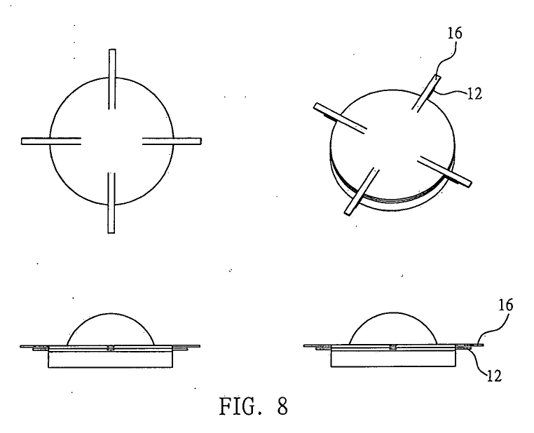

Referring to FIG. 8, a schematic view of the fabricating method in accordance with a second embodiment of the power package of the present invention is shown, which is different from the fabricating method of the power package of the present invention shown in FIG. 7, in that, an insulation layer or a conductive layer can be stacked on the original thin metal member 12, and another thin metal member 16 is further stacked thereon. That is, the insulation layer or conductive layer is positioned between the thin metal member 12 and said another thin metal member 16. The stacking structure can increase the number of conductive leads.

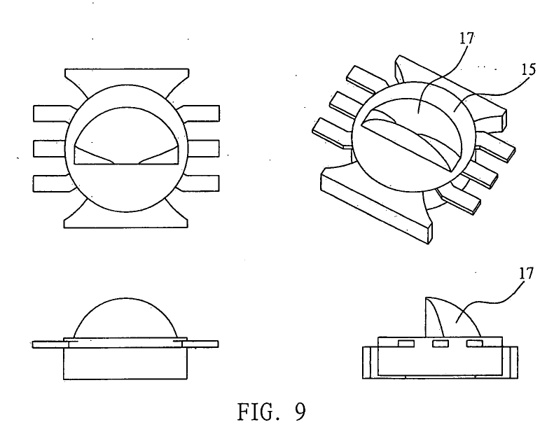

Referring to FIG. 9, a schematic view of the fabricating method in accordance with a third embodiment of the power package of the present invention is shown, which is different from the fabricating method of the power package of the present invention shown in FIG. 7, in that, at least a light reflecting member 17 can be arranged in the original encapsulant 15. The light reflecting member 17 can be semicircle shell-shaped or elliptic shell-shaped which is similar to car lampshades, which can change the light path and focus the light so as to increase the illumination.

Referring to FIGS. 3 to 6, a schematic view of the fabricating method in accordance with a first embodiment of the power package of the present invention is shown. The fabricating method of the power package of the present invention comprises the following steps: combining a thick metal member 11 having at least a light reflecting portion 112 formed thereon in advance and at least a thin metal member 12 having a plurality of leads for electrically connecting the power package to external devices, therefore forming a conductive structure 1; arranging at least a light emitting chip 13 in at lest a light reflecting portion 112 on the thick metal member 11, and electrically connecting the light emitting chip 13 to the thin metal member 12; and forming an encapsulant 15 for encapsulating the light emitting chip 13 and covering a portion of the conductive structure 1.

As can be seen from the above description, in the power package and fabricating method disclosed in the present invention, the conductive structure 1 has a simple structure and is easy to be fabricated and the fabricating cost is reduced. At the same time, the pattern design, shape design and surface film plating of the conductive structure 1 can be independently performed, therefore benefits on design flexibility and various functions can be achieved, and the heat conducting effect can be improved.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A power package comprising:
a conductive structure comprising a thick metal member and a thin metal member, the thick metal member having a light reflecting portion, the thin metal member having at least a conductive lead;
a light emitting chip arranged in the light reflecting portion of the thick metal member and electrically connected to the thin metal member; and
an encapsulant for encapsulating the light emitting chip and covering parts of the thick metal member and the thin metal member; characterized in that the light reflecting portion of the thick metal member and the conductive lead of the thin metal member are formed at one time before the thick metal member is combined with the thin metal member.

2. The power package as claimed in claim 1, wherein the thick metal member further comprises a base.

3. The power package as claimed in claim 2, wherein the base is used for carrying and securing the encapsulant.

4. The power package as claimed in claim 1, wherein the thick metal member is performed by a bright silver plating to increase light reflection of the light emitting chip.

5. The power package as claimed in claim 4, wherein the bright silver plating adopts one of an electrical plating method and a surface coating method.

6. The power package as claimed in claim 1, wherein the light reflecting portion is formed by one of a planar surface, a concave surface and a convex surface.

7. The power package as claimed in claim 1, wherein the thick metal member has a bottom portion and a part of a lateral side exposed to a region uncovered by the encapsulant.

8. The power package as claimed in claim 1, wherein the light reflecting portion is used for reflecting light generated by the light emitting chip.

9. The power package as claimed in claim 1, wherein the thin metal member comprises two conductive leads.

10. The power package as claimed in claim 1, wherein the thin metal member is performed by a foggy silver plating.

11. The power package as claimed in claim 10, wherein the foggy silver plating adopts one of an electrically plating method and a surface coating method.

12. The power package as claimed in claim 1, wherein the thick metal member and the thin metal member are made of identical or different materials.

13. The power package as claimed in claim 1, wherein the thick metal member and the thin metal member are plated with identical or different light reflecting materials.

14. The power package as claimed in claim 1, wherein the encapsulant is one selected from the group consisting of a resin, a glass and a transparent plastic.

15. A power package fabricating method comprising following steps:
combining a thick metal member having a light reflecting portion with a thin metal member having at least a conductive lead, to form a conductive structure;
installing a light emitting chip in the light reflecting portion of the thick metal member, and electrically connecting the light emitting chip to the thin metal member; and
forming an encapsulant for encapsulating the light emitting chip and covering a portion of the conductive structure, characterized in that the light reflecting portion of the thick metal member and the conductive lead of the thin metal member are formed at one time before the thick metal member is combined with the thin metal member, the design flexibility of the thick metal member and the thin metal member before the combination is thus promoted.

16. The power package fabricating method as claimed in claim 15, wherein the thick metal member and the thin metal member are formed by a processing method.

17. The power package fabricating method as claimed in claim 16, wherein the processing method is one of a punching process and an etching process.

18. The power package fabricating method as claimed in claim 15, wherein the thick metal member further comprises a base.

19. The power package fabricating method as claimed in claim 15, wherein the thin metal member comprises two conductive leads.

20. The power package fabricating method as claimed in claim 15, wherein the thick metal member is performed by a bright silver plating for increasing a light reflection of the light emitting chip.

21. The power package fabricating method as claimed in claim 20, wherein the bright silver plating adopts one of an electrical plating method and a surface coating method.

22. The power package fabricating method as claimed in claim 15, wherein the thin metal member is performed by a foggy silver plating for increasing a yield rate of wire bonding electrically connecting to the light emitting chip.

23. The power package fabricating method as claimed in claim 22, wherein the foggy silver plating adopts one of an electrically plating method and a surface coating method.

24. The power package fabricating method as claimed in claim 15, wherein the thick metal member is combined with the thin metal member by an attaching means.

25. The power package fabricating method as claimed in claim 24, wherein the attaching means is one of the a gluing, a punching, a mortising and an AC/DC soldering means.
